(19) United States
(12) Patent Application Publication
(10) Pub. No.: US 2024/0006844 A1
(43) Pub. Date: Jan. 4, 2024

(54) Semiconductor Optical Device

(71) Applicant: Nippon Telegraph and Telephone Corporation, Tokyo (JP)

(72) Inventors: Tatsuro Hiraki, Musashino-shi, Tokyo (JP); Shinji Matsuo, Musashino-shi, Tokyo (JP); Takuma Aihara, Musashino-shi, Tokyo (JP)

(21) Appl. No.: 18/251,330

(22) PCT Filed: Nov. 22, 2021
(86) PCT No.: PCT/JP2021/042762

§ 371 Date: May 1, 2023

Related U.S. Application Data
(63) Continuation-in-part of application No. PCT/JP2020/043575, filed on Nov. 24, 2020.

(51) Int. Cl. H01S 5/026; H01S 5/343

(52) U.S. Cl. CPC H01S 5/0265; H01S 5/34313; H01S 5/34346; H01S 5/0268

(57) ABSTRACT

A semiconductor photonic device includes a first cladding layer formed on a substrate formed with Si, a semiconductor layer formed on the first cladding layer, and a second cladding layer formed on the semiconductor layer. In the semiconductor layer, an active layer, and a p-type layer and an n-type layer disposed in contact with the active layer while sandwiching the active layer in a planar view are formed. A p-type electrode is electrically connected to the p-type layer, and an n-type electrode is electrically connected to the n-type layer. The active layer is formed in a core shape extending in a predetermined direction. This semiconductor photonic device also includes an optical coupling layer that is buried in the first cladding layer in such a manner as to be optically coupled to the active layer, and is formed in a core shape extending along the active layer.

### TECHNICAL FIELD

The present invention relates to semiconductor photonic devices that can be a laser and an optical modulator.

### BACKGROUND ART

A technology for integrating group III-V semiconductors on a Si optical waveguide circuit is a key technology for reducing the sizes and lowering the costs of optical communication transmitters and receivers that include lasers and passive waveguide circuits. In recent years, group III-V semiconductors on Si have attracted attention as materials for manufacturing not only lasers but also high-speed and high-efficiency external modulators. Particularly, an electro-absorption optical modulator (EAM) using a group III-V semiconductor is a key component in manufacturing high-speed optical transmitters that consume less power.

A device using a group III-V semiconductor has been developed as an EAM that can be integrated on a Si optical waveguide circuit, and high-speed and high-efficiency light intensity modulation has been demonstrated (see Non Patent Literature 1). This EAM has a vertical p-i-n diode structure that sandwiches the active layer of a multiple quantum well (MQW) structure with an n-type group III-V semiconductor layer and a p-type group III-V semiconductor layer. The EAM of Non Patent Literature 1 applies an electric field in a direction perpendicular to the active layer with the above-described vertical p-i-n structure, to modulate light intensity with a quantum confined Stark effect (QCSE).

### CITATION LIST

### Non Patent Literature

Non Patent Literature 1: Y. Tang et al., “Over 67 GHz bandwidth hybrid silicon electroabsorption modulator with asymmetric segmented electrode for 1.3 μm transmission”, Optics Express, vol. 20, no. 10, pp. 11529-11535, 2012.

### SUMMARY OF INVENTION

### Technical Problem

The conventional EAM described above has a vertical structure, and has a waveguide structure with a mesa width of about 1 to 2 μm, to strongly confine guided light in the active layer. In such a structure, it is not easy to reduce the junction area in the p-i-n structure. Therefore, the junction capacitance in the p-i-n structure is very large, and the CR band is normally narrow. For this reason, a high-speed operation by a lumped-constant electrode structure is difficult, and power consumption and costs cannot be easily lowered.

The present invention has been made to solve the above problem, and aims to lower power consumption and costs of a semiconductor photonic device that is integrated on a Si optical waveguide circuit and is formed with a group III-V semiconductor.

### Solution to Problem

A semiconductor photonic device according to the present invention includes: a first cladding layer formed on a substrate; a semiconductor layer that is formed on the first cladding layer, and is formed with a group III-V compound semiconductor; an active layer that is formed in the semiconductor layer, has a core shape extending in a predetermined direction, and is formed with a group III-V compound semiconductor; a p-type layer and an n-type layer that are formed in the semiconductor layer, sandwich the active layer in a planar view, are in contact with the active layer, and are formed with a group III-V compound semiconductor; a second cladding layer formed on the semiconductor layer, including a region in which the active layer is formed; an optical coupling layer that is buried in the first cladding layer so as to be optically coupled to the active layer, and is formed in a core shape extending along the active layer; a p-type electrode connected to the p-type layer; and an n-type electrode connected to the n-type layer. In the semiconductor photonic device, the optical coupling layer is formed with a material that absorbs less light being guided in the active layer than the p-type layer and the n-type layer.

A semiconductor photonic device according to the present invention includes: a first cladding layer formed on a substrate; a semiconductor layer that is formed on the first cladding layer, and is formed with a group III-V compound semiconductor; an active layer that is formed in the semiconductor layer, has a core shape extending in a predetermined direction, and is formed with a group III-V compound semiconductor; a p-type layer and an n-type layer that are formed in the semiconductor layer, sandwich the active layer in a planar view, are in contact with the active layer, and are formed with a group III-V compound semiconductor; a second cladding layer formed on the semiconductor layer, including a region in which the active layer is formed; an optical coupling layer that is buried in the first cladding layer so as to be optically coupled to the active layer, and is formed in a core shape extending along the active layer; a p-type electrode connected to the p-type layer; and an n-type electrode connected to the n-type layer. In the semiconductor photonic device, the optical coupling layer is formed with a material that absorbs less light being guided in the active layer than the p-type layer.

### Advantageous Effects of Invention

As described above, according to the present invention, an optical coupling layer that is buried in a first cladding layer and extends along an active layer is provided so as to be optically coupled to the active layer that is formed above the first cladding layer and is formed with a group III-V compound semiconductor. Thus, it is possible to lower power consumption and costs of a semiconductor photonic device that is integrated on a Si optical waveguide circuit and is formed with a group III-V semiconductor.

### BRIEF DESCRIPTION OF DRAWINGS

FIG. 1 is a cross-sectional diagram illustrating a configuration of a semiconductor photonic device according to a first embodiment of the present invention.

FIG. 2A is a characteristics diagram illustrating the dependence of the fill factor in an active layer 105 on the core width of an optical coupling layer 103.

FIG. 2B is a characteristics diagram illustrating the dependence of the fill factor in a p-type layer 106 on the core width of the optical coupling layer 103.

FIG. 3A is a characteristics diagram illustrating the results of calculation of amounts of absorption coefficient changes in light guided in the semiconductor photonic device due to an external electric field.

FIG. 3B is a characteristics diagram illustrating the results of calculation of absorption by the p-type layer 106 (p-InP).

FIG. 3C is a characteristics diagram illustrating the results of calculation of the dependence of the fill factor in the well layers forming the active layer 105 having a multiple quantum well structure, on the core width of the optical coupling layer 103.

FIG. 4 is a characteristics diagram illustrating changes with temperature in the relationship between the absorption edge wavelength of the material forming the active layer of the semiconductor photonic device and the wavelength of guided light.

FIG. 5 is a cross-sectional diagram illustrating another configuration of a semiconductor photonic device according to the first embodiment of the present invention.

FIG. 6 is a cross-sectional diagram illustrating a configuration of a semiconductor photonic device according to a second embodiment of the present invention.

FIG. 7 is a cross-sectional diagram illustrating another configuration of a semiconductor photonic device according to the second embodiment of the present invention.

FIG. 8 is a plan view illustrating a configuration of a semiconductor photonic device according to a third embodiment of the present invention.

FIG. 9 is a plan view illustrating another configuration of a semiconductor photonic device according to the third embodiment of the present invention.

### DESCRIPTION OF EMBODIMENTS

The following is a description of semiconductor photonic devices according to embodiments of the present invention.

### First Embodiment

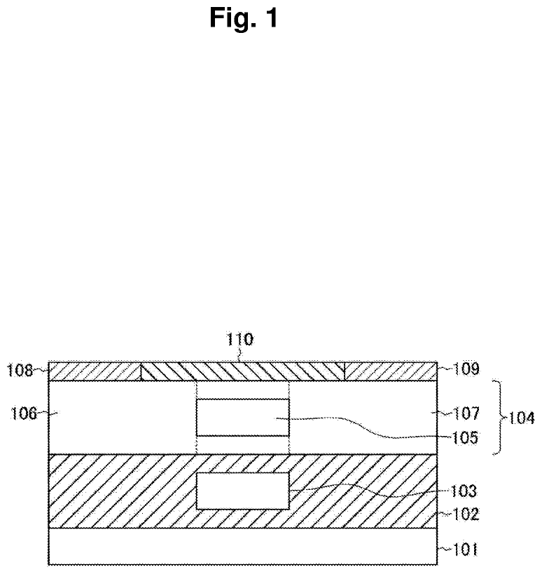

First, a configuration of a semiconductor photonic device according to a first embodiment of the present invention is described with reference to FIG. 1. This semiconductor photonic device includes a first cladding layer 102 formed on a substrate 101 formed with Si, a semiconductor layer 104 formed on the first cladding layer 102, and a second cladding layer 110 formed on the semiconductor layer 104, for example.

In the semiconductor layer 104, an active layer 105, and a p-type layer 106 and an n-type layer 107 disposed in contact with the active layer 105 while sandwiching the active layer 105 in a planar view are also formed. Accordingly, this semiconductor photonic device is a lateral p-i-n. The active layer 105 is of i-type. A p-type electrode 108 is electrically connected to the p-type layer 106, and an n-type electrode 109 is electrically connected to the n-type layer 107. The active layer 105 is formed in a core shape extending in a predetermined direction (waveguide direction). For example, the active layer 105 can be buried in the semiconductor layer 104. Here, the active layer 105 can have a bulk structure. Also, the active layer 105 can have a multiple quantum well structure. Meanwhile, the second cladding layer 110 is formed on the semiconductor layer 104 including the region in which the active layer 105 is formed.

Each of the semiconductor layer 104 and the active layer 105 is formed with a predetermined group III-V compound semiconductor. The p-type layer 106 and the n-type layer 107 are formed by introducing an impurity exhibiting the corresponding conductivity type into the semiconductor layer 104 in the regions sandwiching the active layer 105. The semiconductor layer 104 can be formed with InP, for example. Meanwhile, the active layer 105 can be formed with InGaAsP. Further, the first cladding layer 102 and the second cladding layer 110 can be formed with an insulating material such as SiO₂. As the first cladding layer 102 and the second cladding layer 110 are formed with this type of material, the difference in refractive index between the semiconductor layer 104 and the active layer 105, each of which is formed with a formed with a group III-V compound semiconductor, can be made larger.

The semiconductor layer 104 can have a thickness of 230 nm. The active layer 105 can have a thickness of 150 nm. Also, the active layer 105 can have a width of about 600 nm in a cross-sectional shape perpendicular to the waveguide direction.

This semiconductor photonic device also includes an optical coupling layer 103 that is buried in the first cladding layer 102 in such a manner as to be optically coupled to the active layer 105, and is formed in a core shape extending along the active layer 105. The optical coupling layer 103 is formed in a region below the active layer 105 when viewed from the side of the substrate 101. For example, the optical coupling layer 103 is formed immediately below the active layer 105 when viewed from the side of the substrate 101. The optical coupling layer 103 is formed with a material that absorbs less light being guided in the active layer 105 than the p-type layer 106 and the n-type layer 107. Also, the optical coupling layer 103 can be formed with a material that absorbs less light being guided in the active layer 105 than the p-type layer 106. The optical coupling layer 103 can be formed with Si, for example. Also, the optical coupling layer 103 can be formed with SiN, for example.

In the semiconductor photonic device according to the first embodiment, the active layer 105, the first cladding layer 102 and the second cladding layer 110 sandwiching the active layer 105 in a vertical direction, and the p-type layer 106 and the n-type layer 107 sandwiching the active layer 105 in a horizontal direction constitute an optical waveguide having the active layer 105 as its core. Light is guided in this optical waveguide in the direction in which the active layer 105 extends (the direction from the front side toward the back side of the paper surface of FIG. 1). Accordingly, this semiconductor photonic device can be called a waveguide-type photonic device.

When a reverse bias is applied to the p-type electrode 108 and the n-type electrode 109 of this semiconductor photonic device, the absorption coefficient in the active layer 105 changes because of the Franz-Keldysh effect. With this effect, light guided in the optical waveguide having the active layer 105 as its core can be modulated. For example, the first cladding layer 102 and the second cladding layer 110 are formed with SiO₂, so that light can be strongly confined in the active layer 105 due to a large refractive index difference from the group III-V compound semiconductor, and great intensity modulation can be performed even at a low voltage. As described above, with this semiconductor photonic device, power consumption can be lowered.

In addition to the above, as this semiconductor photonic device includes the optical coupling layer 103, the mode of the optical waveguide having the active layer 105 as its core also includes the optical coupling layer 103, and the spread of this mode in the horizontal direction in a cross-sectional view is reduced around the active layer 105 and the optical coupling layer 103. As a result, the mode of the optical waveguide having the active layer 105 as its core is prevented from spreading to the p-type layer 106 and the n-type layer 107 side, and the overlap of the mode with the p-type layer 106 and the n-type layer 107 can be reduced. As a result, absorption of light being guided by the p-type layer 106 and the n-type layer 107 is reduced, and waveguide loss can be lowered. As is apparent from the above explanation, it is important that the optical coupling layer 103 is located relative to the active layer 105 so that the same mode is formed by the active layer 105 and the optical coupling layer 103. Note that the optical coupling layer 103 can be formed only in the regions in which the p-type layer 106 and the n-type layer 107 are formed in the waveguide direction. In this state, the above-described effect to lower waveguide loss can be achieved.

Also, in this semiconductor photonic device, the thickness of the semiconductor layer 104 (the active layer 105) can be made as thin as several hundreds of nm, and the junction capacitance in the lateral p-i-n structure can be made much smaller than that in a conventional vertical p-i-n structure. In view of the above, with this semiconductor photonic device, it is possible to achieve a higher CR band, or to perform a high-speed operation.

Meanwhile, the group III-V compound semiconductor forming the active layer 105 has a higher refractive index than that of the group III-V compound semiconductor disposed around the active layer 105. In the case of a multiple quantum well structure, the refractive index of the well layer material can be higher than the refractive index of the layer of the group III-V compound semiconductor disposed around the well layer material. InGaAsP has a higher refractive index than that of InP. It is important that the absorption edge wavelength of the group III-V compound semiconductor forming the active layer 105 is shorter than the wavelength of the light to be guided. Therefore, in a case where the active layer 105 is formed with InGaAsP, it is important to adjust each composition of InGaAsP so as to meet the above-described conditions. It is important to set the wavelength of the light to be guided in the optical waveguide having the active layer 105 as its core, within a wavelength range in which band edge absorption of the active layer 105 occurs. The larger the difference (detuning) between the wavelength of the guided light and the absorption edge wavelength of the active layer 105, the smaller the absorption coefficient change per voltage change, but the lower the light loss generated when the applied voltage is 0 V.

Meanwhile, in a case where the active layer 105 has a multiple quantum well structure, the respective layers formed in the multiple quantum well structure are stacked in a direction perpendicular to the substrate 101. In this case, the two-dimensional Franz-Keldysh effect generated by the electric field in the plane direction of the substrate 101 modulates the absorption coefficient in the waveguide direction of the active layer 105 having the multiple quantum well structure. The two-dimensional Franz-Keldysh effect causes a large change in the absorption coefficient near the band edge. On the other hand, in a case where the respective layers in the multiple quantum well structure are stacked in a direction parallel to the plane of the substrate 101, the QCSE effect generated by the electric field in the plane direction of the substrate 101 causes a large change in the absorption coefficient in the active layer 105. In either case, the number of well layers in the multiple quantum well structure is increased, so that the overlap between light and the active layer 105 becomes larger, and a high modulation factor is obtained.

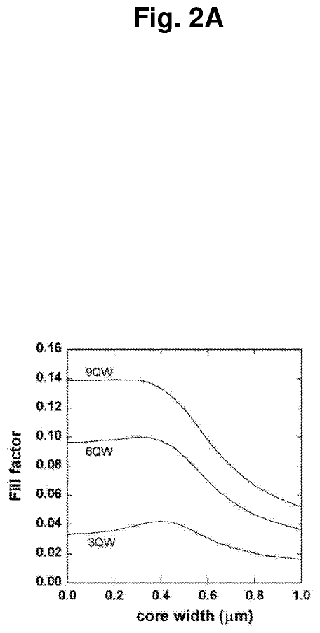

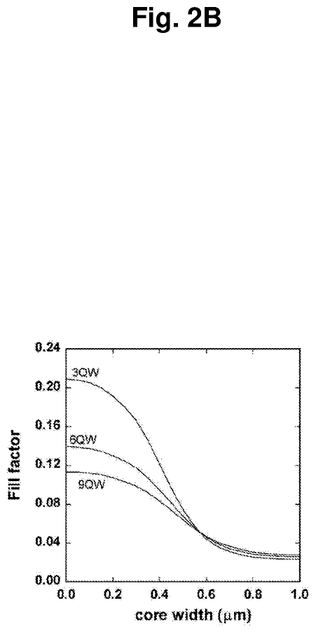

The following is a description of the results of calculation of the dependence of the optical confinement factor (fill factor) in the active layer 105 having a multiple quantum well structure and the dependence of the fill factor in the p-type layer 106, on the width (core width) of the optical coupling layer 103. The calculation was performed for each number of well layers. FIG. 2A shows the dependence of the fill factor in the active layer 105 on the width (core width) of the optical coupling layer 103. FIG. 2B shows the dependence of the fill factor in the p-type layer 106 on the width (core width) of the optical coupling layer 103.

Note that, in any case, the optical coupling layer 103 is formed with Si, and has a thickness of 220 nm. Meanwhile, the first cladding layer 102 is formed with SiO₂, and the semiconductor layer 104 is formed with InP. Further, the distance between the semiconductor layer 104 and the optical coupling layer 103 (the distance in the direction perpendicular to the plane of the substrate 101) is 100 nm. Furthermore, in a multiple quantum well structure, the total number of quantum well layers can be three, six, or nine, for example. In cases where the total number of quantum well layers is three, six, and nine, the thickness of each well layer and the thickness of each barrier layer are the same, and the total thickness of the active layer 105 can be about 50 nm, about 100 nm, and about 150 nm, respectively.

When core width is increased within the range of 0 to 400 nm, the fill factor in the p-type layer 106 monotonously decreases compared with optical confinement in the active layer 105. This indicates that, because of the increase in the core width, the light being guided leaks into the optical coupling layer 103. As can be seen from this fact, waveguide loss can be lowered. Also, it is apparent from this calculation result that an increase in the number of quantum well layers contributes to an increase in optical confinement in the active layer 105 having a multiple quantum well structure, and to a decrease in the fill factor in the p-type layer 106.

For the above-described effect, it is important that the active layer 105 and the optical coupling layer 103 are optically coupled, and for this purpose, it is desirable that the effective refractive indexes of both layers are substantially the same. In the case of InGaAsP and Si, the refractive indexes of both materials are close to each other, and accordingly, the thicknesses of the respective layers are made substantially the same so that the above-described conditions are satisfied.

Meanwhile, in a semiconductor photonic device having a lateral p-i-n structure, the volume of the active layer 105 is small. Therefore, when light with high power enters, the photocarrier density generated in the active layer 105 is likely to become higher. Because of this, the applied electric field is blocked by carriers (electric field blocking), and the response speed of the device drops. In the case of a semiconductor photonic device having a lateral p-i-n structure, the length (absorption length) of the active layer 105 in the waveguide direction is increased, so that the volume of the active layer 105 can be increased, and the input power resistance can be improved. However, to form a device having a long absorption length, the insertion loss (the absorption loss generated in the device with 0 V) needs to be reduced. Otherwise, the output power is not improved even if the input power is increased.

The insertion loss is governed by the absorption generated in the active layer 105 with 0 V and the valence band absorption in the p-type layer 106. In the structure of this embodiment, by optically coupling with the optical coupling layer 103, it is possible to reduce the optical confinement factor in the core of the active layer 105 while reducing the waveguide loss due to the p-type layer 106, as described above. Thus, with the configuration of the first embodiment, it is possible to design a low-loss and long-absorption-length device that is capable of maintaining a high band even at a time of high output.

Also, in a semiconductor photonic device (a lateral p-i-n diode structure) according to the above-described embodiment, the effect to reduce the absorption loss by the optical coupling layer 103 is great in a case where the refractive index difference between the active layer 105 having a buried core structure and the semiconductor layer 104 having the active layer 105 buried therein is small.

An example of such a case is a case where InAlAs layer are used as the barrier layers for the multiple quantum well forming the active layer 105. InAlAs has a wide band gap. In a case where InGaAs or InGaAlAs is used as well layers, a great energy barrier is formed in the conduction band between the well layers and the barrier layers. Therefore, in the multiple quantum well structure having this configuration, it is possible to reduce the thicknesses of the well layers and the barrier layers while reducing tunneling of electrons, and it is possible to expect a strong quantum confinement state and an increase in the absorption coefficient change due to the two-dimensional Franz-Keldysh effect.

On the other hand, the refractive index of InAlAs is smaller than the refractive index of InGaAsP or InGaAlAs. In a case where InAlAs is used in a lateral p-i-n diode structure, the difference in refractive index in the horizontal direction with respect to the plane of the substrate 101 is smaller. That is, absorption by the p-type layer 106 formed with InP can be larger. In the structure of the first embodiment, light leaking in the horizontal direction with respect to the substrate 101 can be reduced by the optical coupling layer 103 buried immediately below the active layer 105. Thus, it is possible to achieve both an increase in modulation efficiency with the InAlAs barrier layers and a decrease in loss with the p-type layer 106, by appropriately designing the core width of the optical coupling layer 103.

Here, a case where the active layer 105 is a nine-layer multiple quantum well (hereinafter referred to as 9QW) including InGaAlAs barriers layer and InGaAlAs well layers is compared with a case where the active layer is a 17-layer multiple quantum well (hereinafter referred to as 17QW) including InAlAs barrier layers and InGaAlAs well layers. Note that the active layer 105 is buried in the thick semiconductor layer 104 formed with InP.

In either configuration, the thickness of the active layer 105 is approximately 150 nm. However, the thickness of each of the well layers and the barrier layers in 17QW is smaller than that in 9QW. Therefore, the number of layers is larger in the case where InAlAs barrier layers are used, even though the cores have approximately the same thickness.

The sum of the thickness of a single InAlAs barrier layer and the thickness of a single InGaAlAs well layer in 17QW is 8.5 nm. As an InAlAs barrier layer forms a high potential barrier in the conduction band between the InAlAs barrier layer and a well layer, tunneling of electrons can be reduced even with such thin well layers and barrier layers. Note that, in either of 9QW and 17QW, the absorption edge wavelength is 1.25 μm, the width of the active layer 105 is 500 nm, and the thickness of the optical coupling layer 103 is 220 nm. Further, the distance between the lower surface (lower edge) of the semiconductor layer 104 and the upper surface (upper edge) of the optical coupling layer 103 (which is the thickness of the first cladding layer 102) is 100 nm. Further, the carrier density in the p-type layer 106 formed with InP is 3×10¹⁸/cm³.

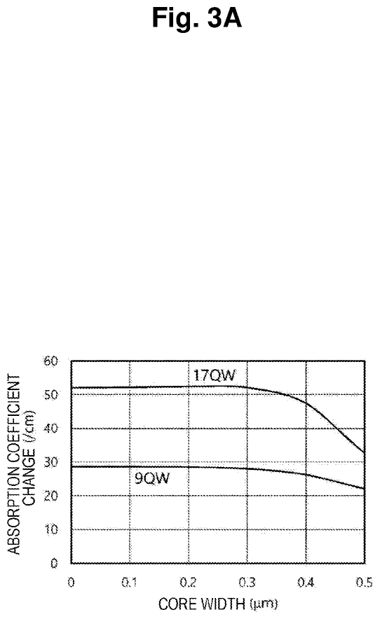

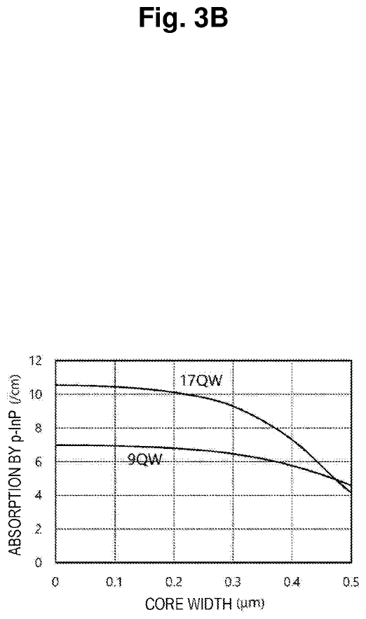

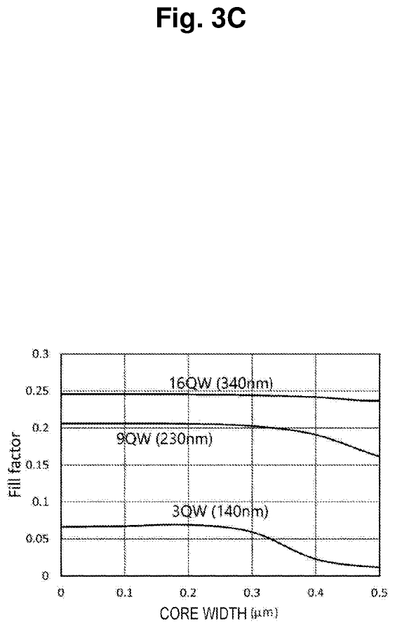

FIG. 3A illustrates the results of calculation of amounts of absorption coefficient changes in light guided in the semiconductor photonic device due to an external electric field under each of the conditions described above. Also, FIG. 3B illustrates the results of calculation of absorption by the p-type layer 106 (p-InP) under each of the conditions described above. As illustrated in FIG. 3A, the amounts of changes in the absorption coefficient of guided light were calculated with the same electric field intensity in both 9QW and 17QW, and the wavelength was 1.32 μm. For simplicity, the homogeneously spreading components of the absorption spectrum were ignored.

As can be seen from FIG. 3A, when the core width of Si as the optical coupling layer 103 is in the range of 0 to 0.6 μm, a larger change in absorption coefficient is obtained in 17QW. Due to the InAlAs barrier layers having a low refractive index, the optical confinement factor in the well layers is slightly lower than that in 9QW, but the contribution of the increase in the amount of absorption coefficient change per well layer greatly exceeds the contribution of the decrease in optical confinement. As a result, 17QW has a higher modulation efficiency than 9QW.

Meanwhile, as can be seen from FIG. 3B, in a case where the optical coupling layer 103 is not used, or where the core width is 0 μm, leakage of light into the p-type layer 106 (p-InP) becomes more conspicuous and the absorption loss becomes greater in 17QW, which uses InAlAs barrier layers. However, by forming a Si waveguide to be the optical coupling layer 103, it becomes possible to make the loss due to the p-type layer 106 smaller than that in 9QW, which uses InGaAlAs barrier layers.

As described above, with a modulator structure that has the lateral p-i-n diode structure, the active layer 105 formed with a multiple quantum well using InAlAs barrier layers, and the optical coupling layer 103, it is possible to obtain a device having a high modulation efficiency and a low loss.

Note that the well layer material is preferably InGaAs or InGaAlAs, which is easily grown together with InAlAs barrier layers.

Also, in the lateral p-i-n diode structure described above, photocarriers generated in the well layers of the active layer 105 are pulled into the p-type layer 106 and the n-type layer 107 by an electric field in a horizontal direction with respect to the plane of the substrate 101. Therefore, the device differs from a device having a p-i-n diode formed in a direction perpendicular to the substrate 101, in that an energy barrier having a large conduction band in the multiple quantum well of the active layer 105 cannot prevent puling of electrons. Because of such a feature, the conduction band energy barrier formed between InAlAs barrier layers and well layers can maintain a high resistance to electric field blocking even in a case where the conduction band energy barrier is greater than the conduction band energy barrier formed between the p-type layer 106 and the well layers of the active layer 105.

Although the thickness of the semiconductor layer 104 is 230 nm in the above description, the thickness is not necessarily limited to that. For example, by increasing both the number of well layers and the thickness of the semiconductor layer 104 without any change in the thicknesses of the well layers and the barrier layers constituting the active layer 105, it is possible to increase the optical confinement factor in the well layer. With a lateral p-i-n diode, an electric field can be uniformly applied to all the layers in the multiple quantum well layer even in a structure in which the total physical thickness of the multiple quantum well forming the active layer 105 is great. Because of this, it is possible to easily pull out photocarriers generated in the well layers, and accordingly, a high resistance to electric field blocking is maintained even if the active layer 105 has a thick structure as described above.

FIG. 3C illustrates the results of calculation of the dependence of the fill factor in the well layers forming the active layer 105 having a multiple quantum well structure, on the core width of the optical coupling layer 103. 3QW is a structure in which the active layer 105 having a three-layer multiple quantum well is buried in the semiconductor layer 104 having a thickness of 140 nm. 9QW is a structure in which the active layer 105 having a nine-layer multiple quantum well is buried in the semiconductor layer 104 having a thickness of 230 nm. 16QW is a structure in which the active layer 105 having a 16-layer multiple quantum well is buried in the semiconductor layer 104 having a thickness of 3400 nm.

Also, under any conditions, the thickness of the optical coupling layer 103 is 220 nm. Further, the distance between the lower surface (lower edge) of the semiconductor layer 104 and the upper surface (upper edge) of the optical coupling layer 103 (which is the thickness of the first cladding layer 102) is 100 nm. Further, the width of the active layer 105 is 600 nm.

As illustrated in FIG. 3C, the thicker the active layer 105 (the semiconductor layer 104), the greater the optical confinement. In this manner, a higher the extinction ratio can be achieved, and voltage can be lowered.

In a case where the active layer 105 is buried through epitaxial growth, the total thickness of the semiconductor layer 104 is preferably equal to or smaller than the critical film thickness at epitaxial growth temperature. For example, in a case where the semiconductor layer 104 is formed with an InP layer joined onto the substrate 101 formed with Si, it is desirable that the total thickness be equal to or smaller than the critical film thickness determined by the difference in thermal expansion coefficient between the substrate 101 and the semiconductor layer 104 formed with InP.

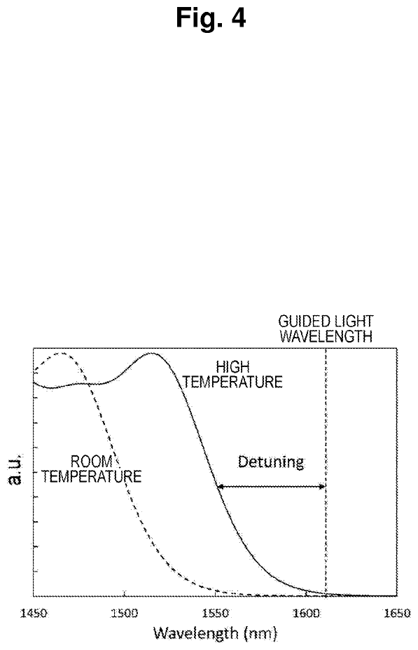

As the temperature of the semiconductor photonic device becomes higher herein, the band gap of the group III-V compound semiconductor forming the active layer 105 becomes narrower. That is, the absorption edge wavelength in the active layer 105 shifts to the long wavelength side at a high temperature. For this reason, detuning is normally set so that the absorption edge wavelength of the material forming the active layer 105 is shorter than the wavelength of guided light even at a maximum possible temperature (see FIG. 4).

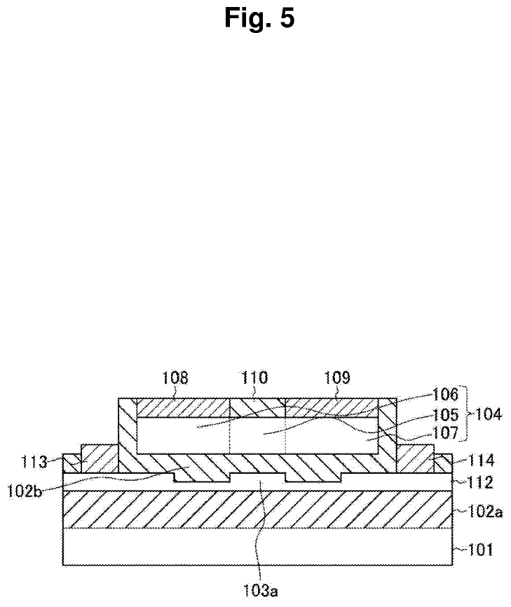

As illustrated in FIG. 4, when the temperature of the semiconductor photonic device drops to the temperature of the room in which the semiconductor photonic device is being used, detuning becomes very large, and the modulation factor greatly decreases. To reduce such changes in characteristics due to a change in environmental temperature, an optical coupling layer 103a having the core shape of a rib-type optical waveguide is formed in an n-type or p-type silicon layer 112, and the optical coupling layer 103a functioning as a heater can be disposed below the active layer 105, as illustrated in FIG. 5.

Note that, in this case, the lower cladding layer includes a lower first cladding layer 102a under the silicon layer 112 and an upper first cladding layer 102b on the silicon layer 112. Further, the semiconductor layer 104 is formed on the upper first cladding layer 102b.

By applying a direct current to the silicon layer 112 with an electrode 113 and an electrode 114, the optical coupling layer 103a serving as a resistor can be made to generate heat and function as a heater. Thus, the temperature of the active layer 105 formed above the optical coupling layer 103a can be made higher.

For example, when the environmental temperature is high, no current is applied to the heater. When the environmental temperature drops, a current is applied to the heater. In this manner, changes in the temperature of the core of the active layer 105 can be reduced. Si has an absorption loss significantly lower than that of a metal that is normally used as a heater, and can have a structure in which the active layer 105 and the heater are optically coupled. Accordingly, the heater can be disposed at a position very close to the active layer 105, and thus, temperature adjustment with low power consumption can be performed.

### Second Embodiment

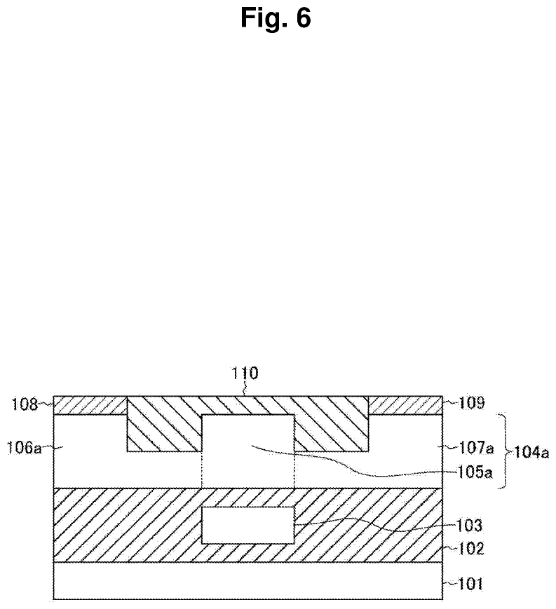

Next, a configuration of a semiconductor photonic device according to a second embodiment of the present invention is described with reference to FIG. 6. This semiconductor photonic device includes a first cladding layer 102 formed on a substrate 101 formed with Si, a semiconductor layer 104a formed on the first cladding layer 102, and a second cladding layer 110 formed on the semiconductor layer 104a, for example.

In the semiconductor layer 104a, an active layer 105a, and a p-type layer 106a and an n-type layer 107a disposed in contact with the active layer 105a while sandwiching the active layer 105a in a planar view are also formed. Accordingly, this semiconductor photonic device is a lateral p-i-n. The active layer 105a is of i-type. A p-type electrode 108 is electrically connected to the p-type layer 106a, and an n-type electrode 109 is electrically connected to the n-type layer 107a.

In the second embodiment, the active layer 105a includes a protruding portion formed in the semiconductor layer 104a between the p-type layer 106a and the n-type layer 107a, and has the core shape of a so-called rib-type optical waveguide. Note that the active layer 105a extends in a predetermined direction. The semiconductor layer 104a is made thinner in predetermined regions on both sides of the portion to be the active layer 105a, so that the above-described structure can be obtained. Accordingly, the semiconductor layer 104a is formed with the same group III-V compound semiconductor as the active layer 105a. Note that the p-type layer 106a and the n-type layer 107a are formed by introducing an impurity exhibiting the corresponding conductivity type into the semiconductor layer 104a in the regions sandwiching the active layer 105a, as in the first embodiment.

In the second embodiment, the active layer 105a can also have a bulk structure. Also, the active layer 105a can have a multiple quantum well structure. Meanwhile, the second cladding layer 110 is formed on the semiconductor layer 104a including the region in which the active layer 105a is formed.

The semiconductor layer 104a and the active layer 105a can be formed with InGaAsP, for example. Further, the first cladding layer 102 and the second cladding layer 110 can be formed with an insulating material such as SiO₂. As the first cladding layer 102 and the second cladding layer 110 are formed with this type of material, the difference in refractive index between the semiconductor layer 104a and the active layer 105a, each of which is formed with a formed with a group III-V compound semiconductor, can be made larger.

Further, this semiconductor photonic device also includes an optical coupling layer 103 that is buried in the first cladding layer 102 in such a manner as to be optically coupled to the active layer 105a, and is formed in a core shape extending along the active layer 105a. The optical coupling layer 103 is formed in a region below the active layer 105a when viewed from the side of the substrate 101. For example, the optical coupling layer 103 is formed immediately below the active layer 105a when viewed from the side of the substrate 101. The optical coupling layer 103 is formed with a material that absorbs less light being guided in the active layer 105a than the p-type layer 106a. The optical coupling layer 103 can be formed with Si, for example.

In the semiconductor photonic device according to the second embodiment, the active layer 105a, the first cladding layer 102 and the second cladding layer 110 sandwiching the active layer 105a in a vertical direction, and the p-type layer 106a and the n-type layer 107a sandwiching the active layer 105a in a horizontal direction constitute an optical waveguide having the active layer 105a as its core. Light is guided in this optical waveguide in the direction in which the active layer 105a extends (the direction from the front side toward the back side of the paper surface of FIG. 6). Accordingly, this semiconductor photonic device can be called a waveguide-type photonic device.

In this structure, a large refractive index difference can also be formed between the active layer 105a and the second cladding layer 110 also in a horizontal direction with respect to the substrate 101. Accordingly, it is possible to achieve stronger optical confinement in the active layer 105a is than in the case of the configuration illustrated in FIG. 1. As a result, according to the second embodiment, it is possible to perform great intensity modulation even at a low voltage. However, since the semiconductor layer 104a is made thinner on both sides of the active layer 105a, the series resistance of the device having a lateral p-i-n structure becomes higher. Where the thickness of the thinned portions is smaller, the height of the protruding portion in the active layer 105a is larger, and the optical confinement becomes greater, but the resistance also becomes higher. Therefore, in this configuration, the modulation factor and the CR band are in a trade-off relationship. The thickness of the semiconductor layer 104a on both sides of the active layer 105a is set in accordance with target performance.

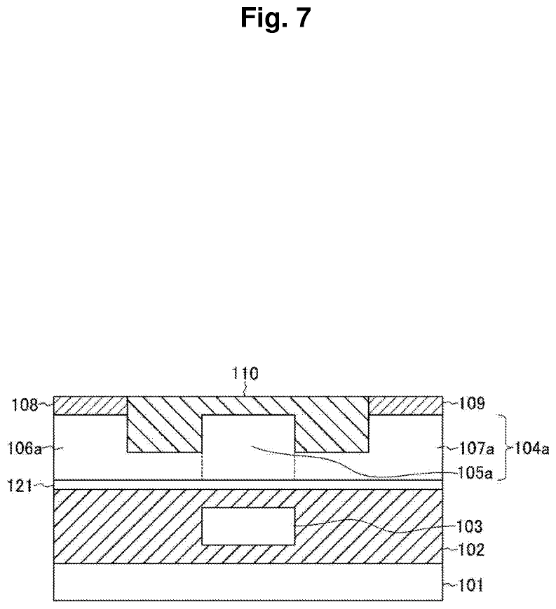

Alternatively, as illustrated in FIG. 7, a cap layer 121 formed with InP can be provided between the semiconductor layer 104a and the first cladding layer 102. A configuration in which the semiconductor layer 104a formed with a group III-V compound semiconductor is disposed above the first cladding layer 102 formed with SiO₂ can be formed by bonding, for example.

The semiconductor layer 104a formed with InGaAsP is formed (crystal-grown) on another substrate formed with InP. Meanwhile, a well-known silicon-on-insulator (SOI) substrate is prepared, and patterning is performed on a surface silicon layer on a buried insulating layer, to form the optical coupling layer 103. An insulating material is then deposited on the buried insulating layer so as to fill the formed optical coupling layer 103. As a result, a configuration in which the first cladding layer 102 formed with the buried insulating layer and the deposited insulating material is formed on the substrate 101, and the optical coupling layer 103 is buried in the first cladding layer 102 can be manufactured.

Next, the semiconductor layer 104a formed on the other substrate is bonded to the first cladding layer 102 in which the optical coupling layer 103 is embedded, and after that, the other substrate is removed. When the semiconductor layer 104a formed with InGaAsP is crystal-grown on another substrate herein, it is not easy to form the final surface with InGaAsP, and the final surface is normally terminated with an InP layer. In this manner, the terminated InP layer turns into the cap layer 121, and the above-described bonding is to bond the cap layer 121 to the first cladding layer 102.

In this manner, the step of forming the active layer 105a in the semiconductor layer 104a to which the first cladding layer 102 is bonded via the cap layer 121, and the step of introducing an n-type impurity and a p-type impurity are carried out. After that, the second cladding layer 110 is formed, and the p-type electrode 108 and the n-type electrode 109 are formed. Thus, the optical semiconductor photonic device according to the second embodiment illustrated in FIG. 7 can be manufactured.

### Third Embodiment

Although cases where a semiconductor photonic device is mainly used as an optical modulator have been described in the above embodiments, a semiconductor photonic device according to the present invention can also be a laser. For example, in the semiconductor photonic device described with reference to FIG. 1, a resonator that resonates in the waveguide direction of the active layer 105 is provided, so that the semiconductor photonic device can be a laser. The resonator can be formed with a diffraction grating, for example.

This diffraction grating can be formed on the active layer 105, for example. In this case, the semiconductor photonic device can be a so-called distributed feedback (DFB) laser. Also, in the DFB laser, the amount of current to be injected into the active layer 105 or the temperature of the device can be adjusted, for example, to obtain a wavelength change.

Alternatively, a distributed Bragg reflector (DBR) in which a diffraction grating is formed in its core is provided on either side or one side of the region of the active layer 105 in the waveguide direction, so that the semiconductor photonic device can be a DBR laser. Further, the DBR laser can change wavelength, taking advantage of a carrier plasma effect generated by current injection into a DBR region independent of the active region.

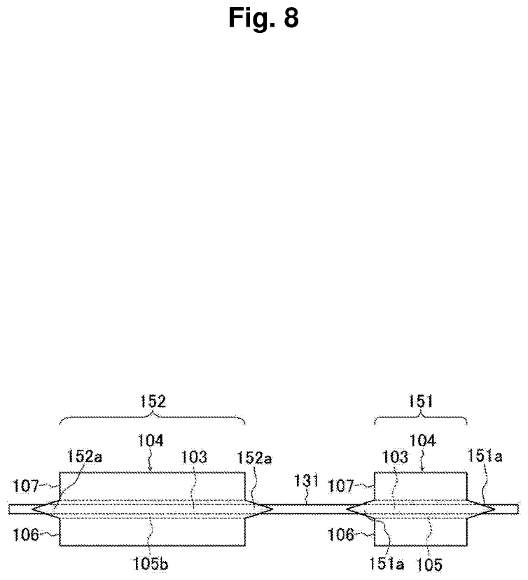

The above-described semiconductor photonic device designed as a laser structure, and a semiconductor photonic device designed as an optical modulator can be integrated on the same substrate. For example, as illustrated in FIG. 8, an optical modulator 151 and a laser 152 can be optically connected directly to each other by a single-mode optical waveguide formed with a core 131. The optical modulator 151 includes an optical coupling layer 103, a semiconductor layer 104, an active layer 105, a p-type layer 106, and an n-type layer 107, as in the first embodiment described above. Also, the laser 152 includes an optical coupling layer 103, a semiconductor layer 104, an active layer 105b, a p-type layer 106, and an n-type layer 107, as in the first embodiment described above. Further, the core 131 is connected to (continuous with) the optical coupling layer 103 of each of the optical modulator 151 and the laser 152.

Here, the active layer 105 and the active layer 105b can have the same configuration, or can have different configurations from each other. For example, the active layer 105 can have a bulk structure, and the active layer 105b can have a multiple quantum well structure. Also, to optimize the modulation efficiency of the optical modulator 151 and optimize the oscillation efficiency of the laser 152, an optimum material can be used for each of the active layer 105 and the active layer 105b. In this case, the material of the active layer 105 and the material of the active layer 105b are different. For example, the active layer 105 can be formed with InGaAsP, and the active layer 105b can be formed with InGaAlAs.

Further, the semiconductor layer 104 of the optical modulator 151 includes tapered portions 151a that taper in a planar view at locations farther from the optical modulator 151 in the waveguide direction, and mode conversion is performed on the single-mode optical waveguide formed with the core 131. Likewise, the semiconductor layer 104 of the laser 152 also includes tapered portions 152a that taper in a planar view at locations farther from the laser 152 in the waveguide direction, and mode conversion is performed on the single-mode optical waveguide formed with the core 131.

Laser light output from the laser 152 enters the optical modulator 151 via the single-mode optical waveguide, and the light intensity is modulated. To form a configuration that performs the above-mentioned mode conversion, it is desirable that the respective optical coupling layers 103 of the optical modulator 151 and the laser 152 have the same thickness, and the effective refractive indexes of the semiconductor layer 104 and the respective optical coupling layers 103 are substantially close to each other. Further, from the viewpoint of ease of integration with the Si waveguide circuit to be integrated together with the laser 152 and the optical modulator 151, the thicknesses of the optical coupling layers 103 and the first cladding layers 102 (not illustrated in FIG. 8) are preferably the same between the laser 152 and the optical modulator 151.

Further, as the thicknesses of the respective semiconductor layers 104 in the laser 152 and the optical modulator 151 are made the same, wafer-level integration through an epitaxial growth process becomes possible. For example, the following known manufacturing techniques can be adopted. First, patterning is performed on the surface silicon layer on the buried insulating layer of a SOI substrate, to form the optical coupling layer 103. An insulating material is then deposited on the buried insulating layer so as to fill the formed optical coupling layer 103, and this surface is planarized. As a result, a configuration in which the first cladding layer 102 formed with the buried insulating layer and the deposited insulating material is formed on the substrate 101, and the optical coupling layer 103 is buried in the first cladding layer 102 can be manufactured.

Meanwhile, an InP layer is formed on another substrate formed with InP, a multiple quantum well layer formed with InGaAsP is then formed, and an InP layer is formed on the formed multiple quantum well layer.

Next, the other substrate on which the InP layer, the multiple quantum well layer, and the InP layer are stacked, and the substrate 101 manufactured with the use of a SOI substrate are bonded onto the surface of the first cladding layer 102 planarized on an InP layer. After that, the other substrate is removed. As a result, the first cladding layer 102 in which the optical coupling layer 103 is buried is formed on the substrate 101, and an InP layer, a multiple quantum well layer, and an InP layer can be stacked on the first cladding layer 102.

Next, patterning is performed so as to leave the InP layer on the surface side and the multiple quantum well layer in the region to be the laser 152. In this patterning, the InP layer on the side of the first cladding layer 102 is left. Next, from the InP layer exposed around the pattern of the multiple quantum well structure formed by the patterning, InGaAsP is regrown to the same thickness as the above-described multiple quantum well layer in the region of the optical modulator 151. InP is then regrown on the InGaAsP, to the same thickness as the InP layer on the multiple quantum well layer.

For example, if the total thickness of InGaAsP and InP in the region of the optical modulator 151 is equal to or smaller than the critical film thickness at the growth temperature in the above-described growth (epitaxial growth), the above-described regrowth process can be adopted.

As described above, the multiple quantum well layer is left in the region of the laser 152, and an InGaAsP layer and an InP layer are regrown in the region of the optical modulator 151. After that, the multiple quantum well layer and the InGaAsP layer are processed into a core shape, to form the active layer 105b of the laser 152 and the active layer 105 of the optical modulator 151. By the processing of the core shape, InP is regrown on the InP layer on the side of the first cladding layer 102 exposed around each active layer 105, so that each active layer 105 is buried therein. As a result, the semiconductor layer 104 in which the active layer 105 is buried is formed in each region of the laser 152 and the optical modulator 151.

Next, ions of Zn to be an acceptor are introduced into the region to be the p-type layer 106 by a predetermined diffusion process, and ions of Si to be a donor are introduced into the region to be the n-type layer 107. After that, a diffraction grating is formed on the surface of the semiconductor layer 104 on the active layer 105 in the region of the laser 152, a p-type electrode 108 and an n-type electrode 109 are formed, and a second cladding layer 110 is formed.

Here, in a case where the laser 152 and the optical modulator 151 are integrated on the same substrate as described above, it is also possible to reduce temperature changes due to self-heating of the optical modulator 151. For example, if the optical modulator 151 is covered with an insulator having a low thermal conductivity, such as SiO₂, the optical modulator 151 has a very high thermal resistance. Because of this, the temperature rise to be caused by a photocurrent is extremely large. When the environmental temperature drops from high temperature to room temperature, detuning of the optical modulator 151 is to become greater, but the output of the integrated laser 152 becomes larger. Therefore, the photocurrent flowing in the optical modulator 151 becomes larger. As a result, self-heating due to the photocurrent contributes to a decrease in the temperature of the active layer 105 in the optical modulator 151.

As the volume of the optical modulator 151 becomes smaller, the self-heating value with respect to the same photocurrent becomes greater. Therefore, forming a small-sized optical modulator 151 is promising. Making the optical modulator 151 smaller is also beneficial in achieving a higher speed. To increase only the thermal resistance of the optical modulator 151, a layer having a low thermal conductivity (such as air, for example) can be disposed only around the optical modulator 151. Also, since the self-heating value increases not only due to a photocurrent but also due to a DC bias applied to the optical modulator 151, it is also effective to increase the DC bias when the environmental temperature drops. When temperature drops, and detuning becomes larger, it is normally preferable to increase the DC bias, also in terms of linearity and the extinction ratio.

Further, since the thermal conductivity of InGaAsP is lower than that of InP, the optical modulator of the rib-type optical waveguide described with reference to FIG. 6 or 7 has a higher thermal resistance and a larger temperature rise due to a photocurrent than those of the optical modulator 151 in which the active layer 105 is buried in the semiconductor layer 104.

Meanwhile, the semiconductor layer 104 of the laser 152 has the same thickness as the semiconductor layer 104 of the optical modulator 151. However, it is important to lower the thermal resistance and obtain a large output. Therefore, a laser structure with a long active layer length is promising. Further, in a case where the laser 152 is a DFB laser, when the temperature drops, the oscillation wavelength shifts to the shorter wavelength side. This contributes to a decrease in the change to be caused in the detuning amount by a temperature change.

As described above, the combination of the laser 152 having a low thermal resistance and the optical modulator 151 having a high thermal resistance makes it possible to form an optical transmitter that is operable over a wide range of temperature.

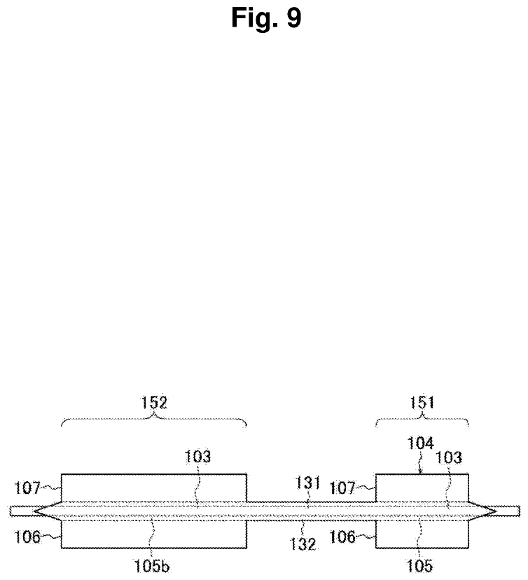

Meanwhile, the optical connection between the laser 152 and the optical modulator 151 is not necessarily connected to the single-mode optical waveguide formed with the core 131, via the tapered portion 152a and the tapered portion 151a. For example, as illustrated in FIG. 9, the optical connection between the laser 152 and the optical modulator 151 can be connection by an optical waveguide formed with a compound core 132 formed with InP, for example. The compound core 132 is connected to each of the semiconductor layers 104. In this case, the core 131 can be disposed under the compound core 132.

As described above, according to the present invention, an optical coupling layer that is buried in a first cladding layer and extends along an active layer is provided so as to be optically coupled to the active layer that is formed above the first cladding layer and is formed with a group III-V compound semiconductor. Thus, it is possible to lower power consumption and costs of a semiconductor photonic device that is integrated on a Si optical waveguide circuit and is formed with a group III-V semiconductor.

Note that the present invention is not limited to the embodiments described above, and it is obvious that many modifications and combinations can be made to them by those skilled in the art within the technical spirit of the present invention.

### REFERENCE SIGNS LIST

101 substrate
102 first cladding layer
103 optical coupling layer
104 semiconductor layer
105 active layer
106 p-type layer
107 n-type layer
108 p-type electrode
109 n-type electrode
110 second cladding layer

1. A semiconductor photonic device comprising:
a first cladding layer formed on a substrate;
a semiconductor layer that is formed on the first cladding layer, and is formed with a group III-V compound semiconductor;
an active layer that is formed in the semiconductor layer, has a core shape extending in a predetermined direction, and is formed with a group III-V compound semiconductor;
a p-type layer and an n-type layer that are formed in the semiconductor layer, sandwich the active layer in a planar view, are in contact with the active layer, and are formed with a group III-V compound semiconductor;
a second cladding layer formed on the semiconductor layer, including a region in which the active layer is formed;
an optical coupling layer that is buried in the first cladding layer so as to be optically coupled to the active layer, and is formed in a core shape extending along the active layer;
a p-type electrode connected to the p-type layer; and
an n-type electrode connected to the n-type layer,
wherein the optical coupling layer is formed with a material that absorbs less light being guided in the active layer than the p-type layer and the n-type layer.

2. A semiconductor photonic device comprising:
a first cladding layer formed on a substrate;
a semiconductor layer that is formed on the first cladding layer, and is formed with a group III-V compound semiconductor;
an active layer that is formed in the semiconductor layer, has a core shape extending in a predetermined direction, and is formed with a group III-V compound semiconductor;
a p-type layer and an n-type layer that are formed in the semiconductor layer, sandwich the active layer in a planar view, are in contact with the active layer, and are formed with a group III-V compound semiconductor;
a second cladding layer formed on the semiconductor layer, including a region in which the active layer is formed;
an optical coupling layer that is buried in the first cladding layer so as to be optically coupled to the active layer, and is formed in a core shape extending along the active layer;
a p-type electrode connected to the p-type layer; and
an n-type electrode connected to the n-type layer,
wherein the optical coupling layer is formed with a material that absorbs less light being guided in the active layer than the p-type layer.

3. The semiconductor photonic device according to claim 1, wherein
the active layer is formed and buried in the semiconductor layer.

4. The semiconductor photonic device according to claim 1, wherein
the active layer is formed with a protruding portion formed in the semiconductor layer, the protruding portion being located between the p-type layer and the n-type layer.

5. The semiconductor photonic device according to claim 1, wherein
the active layer has a multiple quantum well structure.

6. The semiconductor photonic device according to claim 5, wherein
the active layer has a multiple quantum well structure including a barrier layer formed with InAlAs, and
the p-type layer and the n-type layer are formed with InP.

7. The semiconductor photonic device according to claim 1, further comprising
a resonator that resonates in a waveguide direction of the active layer.

8. The semiconductor photonic device according to claim 7, wherein
the resonator includes a diffraction grating.

9. The semiconductor photonic device according to claim 1, wherein
the optical coupling layer is formed with Si.

10. The semiconductor photonic device according to claim 1, wherein
the first cladding layer and the second cladding layer are formed with an insulating material.

11. The semiconductor photonic device according to claim 2, wherein
the active layer is formed and buried in the semiconductor layer.

12. The semiconductor photonic device according to claim 2, wherein
the active layer is formed with a protruding portion formed in the semiconductor layer, the protruding portion being located between the p-type layer and the n-type layer.

13. The semiconductor photonic device according to claim 2, wherein
the active layer has a multiple quantum well structure.

14. The semiconductor photonic device according to claim 2, further comprising
a resonator that resonates in a waveguide direction of the active layer.

15. The semiconductor photonic device according to claim 14, wherein
the resonator includes a diffraction grating.

16. The semiconductor photonic device according to claim 2, wherein
the optical coupling layer is formed with Si.

17. The semiconductor photonic device according to claim 2, wherein
the first cladding layer and the second cladding layer are formed with an insulating material.
